(19) United States
(12) Patent Application Publication
(10) Pub. No.: US 2021/0168942 A1
(43) Pub. Date: Jun. 3, 2021

(54) CONDUCTIVE PATTERN, METHOD FOR FORMING CONDUCTIVE PATTERN, AND DISCONNECTION REPAIRING METHOD

(71) Applicant: SAKAI DISPLAY PRODUCTS CORPORATION, Sakai-shi, Osaka (JP)

(72) Inventor: KIBO WATANABE, Sakai-shi, Osaka (JP)

(21) Appl. No.: 16/477,735

(22) PCT Filed: Jan. 25, 2017
(86) PCT No.: PCT/JP2017/002590

§ 371 Date: Sep. 20, 2019

(51) Int. Cl. H05K 3/22; H05K 1/09; H05K 3/12; H05K 3/38

(52) U.S. Cl. CPC H05K 3/225; H05K 1/097; H05K 3/1241; H05K 3/386; H05K 3/388; H05K 3/1283

(57) ABSTRACT

Provided is a conductive pattern according to an embodiment of the present invention formed on a surface of an inorganic insulating material (12), the conductive pattern having a lower layer (16A) in direct contact with the surface of the inorganic insulating material (12), and a metal nanoparticle sintered material-containing layer (18A) formed on the lower layer (16A). The lower layer (16A) and the metal nanoparticle sintered material-containing layer (18A) are formed using, for example, an ultra-fine inkjet processing device.

### TECHNICAL FIELD

The present invention relates to conductive patterns, methods for forming a conductive pattern, and broken-line repairing methods. More particularly, the present invention is suitably used for repairing a broken line on a wiring board (typically, a TFT substrate) used in a large-sized, high-definition display panel.

### BACKGROUND ART

For example, as liquid crystal display panels have become much larger-sized and/or higher-definition, the width of interconnects (lines of interconnection, also simply referred to as “lines”) such as a gate bus line, source bus line, and lead line (an interconnect for coupling a bus line and a drive circuit together) has become smaller and smaller, which is accompanied by an increase in the frequency of occurrence of a broken line fault. For example, among 4K or 8K liquid crystal display panels is a commercially-available one that has a line-and-space (L/S) of 5 μm/5 μm.

In order to repair a break in a source bus line, a spare interconnect has conventionally been utilized. For example, a spare interconnect is provided at a periphery of a display region (a region where a plurality of pixels are arranged, which is also called an “active region”), one end of a broken source bus line that is not coupled to a drive circuit is coupled to the spare in and a source signal voltage (display signal voltage) is supplied through the spare interconnect, so that the desired source signal voltage is supplied to a pixel located downstream of the break point (the side of the source line farther away from the drive circuit). The spare interconnect is disposed at a periphery of the display region, and therefore, as the size of a liquid crystal display panel increases, the spare interconnect becomes longer, so that problems such as a signal delay and a rounded waveform become significant. Meanwhile, if a spare interconnect extending in parallel to a source bus line is provided in the display region, the signal delay problem can be reduced, but t he pixel aperture ratio decrease. In 4 K or 8K liquid crystal display panels, it is difficult to achieve a sufficient pixel aperture ratio, and there is not room for snare interconnects in the display region.

There is an alternative technique of repairing a broken portion by forming, for example, a tungsten (W) thin film at the broken portion by laser CVD. However, if the tungsten thin film, which has high resistivity, is used in a high-definition liquid crystal display panel, problems such as a signal delay and a rounded waveform may occur.

Patent Document No. 1 describes a method for repairing a broken line by an inkjet technique using a conductive ink containing metal nanoparticles (hereinafter referred to as a “conductive nano-ink”). As the metal nanoparticles, nanoparticles of silver (Ag), copper (Cu), and gold (Au) are used. The metal nanoparticle has the feature that the melting point thereof is lower than that of bulk metal, and therefore, allows the above noble metals, which have low resistivity, to be sintered at a practical temperature. In addition, in recent years, a high-definition inkjet device has been developed that can form interconnects having a line width of about 1 μm.

### CITATION LIST

### Patent Literature

Patent Document No. 1: Japanese Laid-Open Patent Publication No. 2004-134596

### SUMMARY OF INVENTION

### Technical Problem

However, the present inventors have studied to find the problem that if the conductive nano-ink is used to repair a broken line using an inkjet technique, a repaired portion formed of a sintered material of metal nanoparticles has poor adhesion to a glass substrate or an inorganic insulating layer (e.g., a SiN layer or a SiO₂ layer), and therefore, lacks reliability.

This problem occurs not only in repairing a broken line but also in forming or repairing a conductive pattern using the conductive nano-ink. Note that conductive patterns widely include RF antenna patterns, etc., in addition to the above interconnects.

The present invention has been made to solve the above problem. It is an object of the present invention to provide a conductive pattern having improved adhesion to a glass substrate, etc., a method for forming the conductive pattern, and a broken-line repairing method.

### Solution to Problem

A conductive pattern according to one embodiment of the present invention is a conductive pattern formed on a surface of an inorganic insulating material, in which the conductive pattern has a lower layer in direct contact with the surface of the inorganic insulating material, and a metal nanoparticle sintered material-containing layer formed on the lower layer. The adhesion of the lower layer to the surface of the inorganic insulating material is higher than the adhesion of the metal nanoparticle sintered material-containing layer to the surface of the inorganic insulating material. The resistivity of the lower layer is higher than that of the metal nanoparticle sintered material-containing layer.

In one embodiment, the conductive pattern includes a linear pattern formed on the surface of the inorganic insulating material. The linear pattern has a linear conductive layer having a broken portion, the lower layer formed in direct contact with the surface of the inorganic insulating material exposed at at least the broken portion, and the metal nanoparticle sintered material-containing layer continuously formed on the lower layer, and on the linear conductive layer on both sides of the broken portion. The linear pattern may be not only in a straight-line shape but also in a curved-line shape or a bent pattern.

In one embodiment, the linear conductive layer is formed of a metal layer.

In one embodiment, the metal nanoparticle sintered material-containing layer has a resistivity of 1×10⁻⁵ Ω·cm or less. The metal nanoparticles include Au (gold) nanoparticles, Ag (silver) nanoparticles, or Cu (copper) nanoparticles.

In one embodiment, the lower layer has insulating properties.

In one embodiment, the lower layer contains a polyimide.

In one embodiment, the lower layer further contains metal nanoparticles or metal oxide nanoparticles. The metal nanoparticles contained in the lower layer are, for example, of the same type as that of the metal nanoparticles of the metal nanoparticle sintered material-containing layer. The metal oxide nanoparticles are, for example, ITO nanoparticles.

In one embodiment, the lower layer has conductivity, and has a resistivity higher than that of the metal nanoparticle sintered material-containing layer.

In one embodiment, the lower layer contains an ITO (indium tin oxide) nanoparticle sintered material or a Ti (titanium) nanoparticle sintered material.

A method for forming a conductive pattern according to an embodiment of the present invention is a method for forming the conductive pattern according to any of the above embodiments, in which a step of forming the metal nanoparticle sintered material-containing layer includes a step of applying a conductive nano-ink containing metal nanoparticles using an inkjet technique. A step of forming the lower layer may also include a step of applying a liquid material using an inkjet technique.

A broken-line repairing method according to an embodiment of the present invention is a broken-line repairing method including step A of preparing a substrate having a plurality of interconnects on a surface of an inorganic insulating material, step B of identifying a broken portion in the plurality of interconnects, step C of forming a lower layer in direct contact with the surface of the inorganic insulating material exposed at the broken portion, step D of drawing a predetermined pattern on the lower layer, and on an interconnect having the broken portion of the plurality of interconnects on both sides of the broken portion, using a conductive nano-ink containing metal nanoparticles, and step E of sintering the conductive nano-ink of the predetermined pattern by heating. The substrate is, for example, a TFT substrate for use in a liquid crystal display panel or an organic EL display panel. The substrate has an interconnect pattern having a line-and-space (L/S) of 5 μm/5 μm or less.

In one embodiment, step C is a step of forming the lower layer such that the lower layer extends on the interconnect having the broken portion of the plurality of interconnects on both sides of the broken portion.

In one embodiment, step C is a step of forming the lower layer using an insulating material such that the lower layer extends on an interconnect adjacent, to the interconnect having the broken portion.

In one embodiment, step D is performed using an inkjet technique.

In one embodiment, step C includes step C1 of drawing a predetermined pattern by an inkjet technique using a liquid material, and step C2 of heating the liquid material of the predetermined pattern. The broken-line repairing method may further include, prior to step C2, a step of removing a solvent contained in the liquid material.

In one embodiment, steps C1 and D are performed using the same inkjet device.

In one embodiment, step E is performed using infrared laser. The infrared laser is, for example, CO₂ laser, YAG laser, or semiconductor laser. Step C2 may also be performed using infrared laser.

In one embodiment, the broken-line repairing method further includes, prior to step E, a step of removing a solvent contained in the conductive nano-ink.

### Advantageous Effects of Invention

According to the embodiments of the present invention, provided are a conductive pattern having improved adhesion to a glass substrate, etc., a method for forming the conductive pattern, and a broken-line repairing method.

### BRIEF DESCRIPTION OF DRAWINGS

FIG. 1(a) is a plan view schematically showing a break-repaired portion in a TFT substrate 10A according to an embodiment of the present invention, FIG. 1(b) is a schematic cross-sectional view taken along line 1B-1B′ in FIG. 1(a), and FIG. 1(c) is a schematic cross-sectional view taken along line 1C-1C′ in FIG. 1(a).

FIG. 2(a) is a plan view schematically showing a break-repaired portion in a TFT substrate 10B according to another embodiment of the present invention, FIG. 2(b) is a schematic cross-sectional view taken along line 2B-2B′ in FIG. 2(a), and FIG. 2(c) is a schematic cross-sectional view taken along line 2C-2C′ in FIG. 2(a).

### DESCRIPTION OF EMBODIMENTS

A conductive pattern, conductive pattern forming method, and broken-line repairing method according to an embodiment of the present invention will now be described with reference to the accompanying drawings. Although, in the description that follows, a broken-line repairing method for an interconnect (linear conductive layer) on a TFT substrate of a liquid crystal display panel is described, the present invention is not limited to a liquid crystal display panel, and is applicable to an organic EL display panel and ocher wiring boards. The broken-line repairing method according to an embodiment of the present invention is also applicable to repairing of a break in a linear conductive layer different from interconnects. The broken-line repairing method according to an embodiment of the present invention has a significance for repairing a break in a conductive pattern having a line width of less than 10 μm, particularly not more than 5 μm. Furthermore, according to an embodiment of the present invention, a conductive pattern can be formed using a method similar to the broken-line repairing method described below. The conductive pattern includes a linear pattern. The linear pattern includes not only a straight-line pattern but also a curved and a bent pattern. The bent pattern includes, for example, an RF antenna pattern.

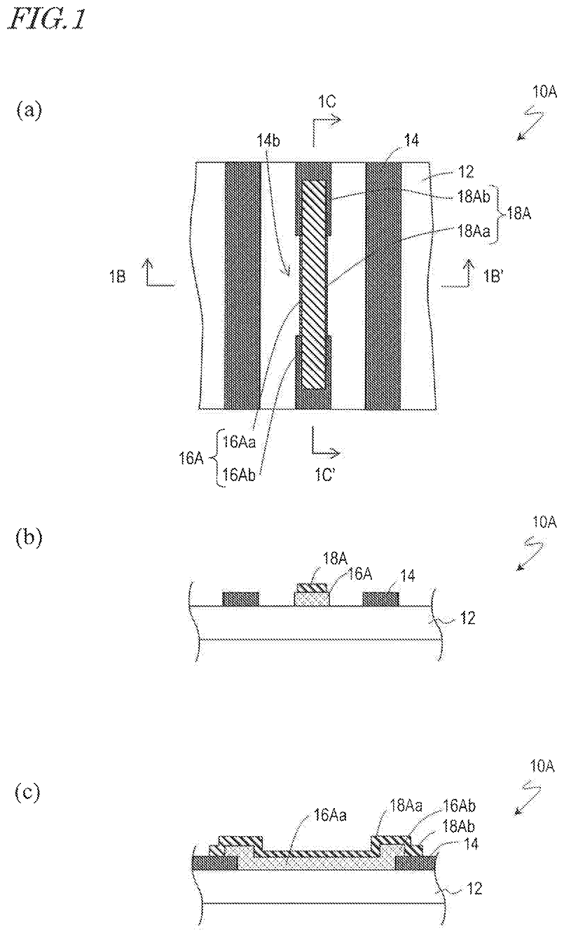

FIGS. 1(a)-1(c) schematically show a structure of a break-repaired portion in a TFT substrate 10A according to an embodiment of the present invention. FIG. 1(a) is a plan view schematically showing a break-repaired portion in the TFT substrate 10A. FIG. 1(b) is a schematic cross-sectional view taken along line 1B-1B′ in FIG. 1(a). FIG. 1(c) is a schematic cross-sectional view taken along line 1C-1C′ in FIG. 1(a). The TFT substrate 10A, which is for use in, for example, a 4K or 8K liquid crystal display panel, has a plurality of interconnects 14 having a line-and-space (L/S) of 5 μm/5 ∥m.

Of three adjacent interconnects 14 shown in FIG. 1(a), a middle interconnect 14 has a broken portion 14b. The broken portion 14b is repaired by a lower layer 16A and a metal nanoparticle sintered material-containing layer 18A.

The TFT substrate 10A shown in FIG. 1(a) has a plurality of interconnects 14 on a surface of a substrate 12. The substrate 12, at least a surface of which is formed of an inorganic insulating material, is typically a glass substrate. An inorganic insulating layer (e.g., a SiN layer or a SiO₂ layer) may be formed on the glass substrate.

The plurality of interconnects 14 are formed of a metal layer, and is formed of, for example, Cu (copper). In high-definition liquid crystal display panels, a gate bus line and/or a source bus line are formed using Cu, which has a low resistance. The interconnects 14 are formed by patterning a Cu film formed by thin film deposition (e.g., sputtering), using a photolithography process. The Cu film has a thickness of, for example, 1 μm or less.

If the interconnect 14 has a width of less than 10 μm, a break is likely to occur in the interconnect 14. Such a break occurs due to, for example, dust adhering to the Cu film during deposition of the Cu film by the thin film deposition, or dust adhering to a photomask in the photolithography process. The broken portion 14b may have a length of as great as 100 μm. If a broken line is repaired using a conductive nano-ink containing metal nanoparticles as described in Patent Document No. 1, the repaired portion formed of a sintered material of the metal nanoparticles may have low adhesion to the glass substrate or the inorganic insulating layer (e.g., a SiN layer or a SiO₂ layer) 12, resulting in insufficient reliability.

The TFT substrate 10A of FIG. 1 has the lower layer 16A that is formed in direct contact with a surface of the substrate (inorganic insulating material) 12 that is exposed at the broken portion 14b of an interconnect 14, and the metal nanoparticle sintered material-containing layer 18A that is continuously formed on the lower layer 16A, and on the interconnect 14 on both sides of the broken portion 14b. The lower layer 16A of FIG. 1 is formed, extending on the interconnect 14 on both sides of the broken portion 14b. Specifically, the lower layer 16A has a portion 16Aa that is formed on the surface of the substrate 12 that is exposed at the broken portion 14b of the interconnect 14, and portions 16Ab formed on the interconnect 14 on both sides of the broken portion 14b. However, the lower layer may be formed only on the surface of the substrate 12 that is exposed at the broken portion 14b of the interconnect 14. In other words, a lower layer having only the portion 16Aa of the lower layer 16A can be used. Note that in order to form a lower layer that completely covers the surface of the substrate 12 that is exposed at the broken portion 14b, the lower layer is preferably formed, extending on the interconnect 14 on both sides of the broken portion 14b, like the lower layer 16A, taking into account an alignment margin for formation of the lower layer, etc.

Here, the lower layer 16A acts to improve the adhesion of the metal nanoparticle sintered material-containing layer 18A. Specifically, the adhesion of the lower layer 16A to the surface of the substrate 12 is greater than the adhesion of the metal nanoparticle sintered material-containing layer 18A to the surface of the substrate 12. Meanwhile, the resistivity of the lower layer 16A is higher than that of the metal nanoparticle sintered material-containing layer 18A.

For example, in order to repair a break in a Cu interconnect 14 having a line width of 5 μm and obtain sufficient conduction, the metal nanoparticle sintered material-containing layer 18A preferably has a resistivity of, for example, 1×10-5 Ω·cm or less. The metal nanoparticle sintered material-containing layer 18A having such a low resistivity is obtained by sintering a conductive nano-ink containing Au (gold) nanoparticles, Ag (silver) nanoparticles, or Cu (copper) nanoparticles. However, a sintered material-containing layer 18A of these metal nanoparticles has low adhesion to the substrate (inorganic insulating material) 12. In other words, it is difficult to form a metal nanoparticle sintered material-containing layer having a low resistivity and great adhesion.

With the above in mind, in the broken-line repairing method according to an embodiment of the present invention, in order to improve the adhesion of the metal nanoparticle sintered material-containing layer 18A to the substrate 12, employed is a configuration in which the lower layer 16A having a higher resistivity than that of the metal nanoparticle sintered material-containing layer 18A is formed on the substrate 12, and the metal nanoparticle sintered material-containing layer 18A is attached to the substrate 12 with the lower layer 16A interposed therebetween.

The lower layer 16A may have insulating properties. In the case where the lower layer 16A has insulating properties, the lower layer 16A can be formed using, for example, a polyimide. By mixing metal nanoparticles with the polyimide, the adhesion of the lower layer 16A to the metal nanoparticle sintered material-containing layer 18A can be further improved. The metal nanoparticles mixed with the polyimide are preferably of the same type as that of the metal nanoparticles of the metal nanoparticle sintered material-containing layer 18A, or alternatively, may be Ti (titanium) nanoparticles. It is known that a Ti film has excellent adhesion to a Cu film. Alternatively, instead of metal nanoparticles, metal oxide nanoparticles such as ITO nanoparticles may be mixed. The lower layer 16A preferably has a thickness of, for example, 1 μm or less. In addition, the metal nanoparticles or metal oxide nanoparticles contained in the lower layer 16A preferably have a particle size of, for example, 0.1 μm or less.

The lower layer 16A may, of course, have conductivity. The lower layer 16A that has conductivity and excellent adhesion to the metal nanoparticle sintered material-containing layer 18A contains, for example, an ITO (indium tin oxide) nanoparticle sintered material or a Ti (titanium) nanoparticle sintered material. In the case where the lower layer 16A has conductivity, the lower layer 16A preferably has a width that is equal to or smaller than the width of a space between adjacent interconnects 14 (here, equal to the width of the interconnect 14). ITO nanoparticles or Ti (titanium) nanoparticles used for formation of the ITO (indium tin oxide) nanoparticle sintered material or the Ti (titanium) nanoparticle sintered material preferably have a particle size of, for example, 0.1 μm or less. This lower layer 16A preferably has a thickness of, for example, 1 μm or less.

The metal nanoparticle sintered material-containing layer 18A is continuously formed on the lower layer 16A, and on the interconnect 14 on both sides of the broken portion 14b. As shown in FIGS. 1(a) and 1(c), a portion 18Aa of the metal nanoparticle sintered material-containing layer 18A is formed on the lower layer 16A, and portions 18Ab of the metal nanoparticle sintered material-containing layer 18A are formed on the interconnect 14 on both sides of the broken portion 14b. The metal nanoparticle sintered material-containing layer 18A preferably has a width smaller than that of the lower layer 16A, taking into account an alignment margin, etc.

The metal nanoparticle sintered material-containing layer 18A is obtained by sintering a conductive nano-ink containing Au (gold) nanoparticles, Ag (silver) nanoparticles, or Cu (copper) nanoparticles. Ag nanoparticles or Cu nanoparticles are preferable in terms of conductivity and cost. The metal nanoparticles preferably have a particle size of, for example, 0.1 μm or less. The metal nanoparticle sintered material-containing layer 18A preferably has a thickness of, for example, 1 μm or less.

As the above metal nanoparticles and metal oxide nanoparticles, those having various particle sizes are commercially available, including, for example, those that can be purchased from SIGMA-ALDRICH.

A broken line in a TFT substrate 10A is repaired as follows, for example.

The TFT substrate 10A has a glass substrate 12 on which a plurality of interconnects 14 are formed, is used in a liquid crystal display panel, and is produced using a known technique.

A broken portion 14b in the plurality of interconnects 14 of the TFT substrate 10A is identified. The broken portion 14b is identified using, for example, an imaging device.

Next, a lower layer 16A is formed on a surface of an inorganic insulating material exposed at the broken portion 14b to be in direct contact with the surface of the inorganic insulating material. At this time, the lower layer 16A is preferably formed, extending on the interconnect 14 on both sides of the broken portion 14b.

A step of forming the lower layer 16A includes, for example, a step of drawing a predetermined pattern by an inkjet technique using a liquid material, and a step of heating the liquid material in the predetermined pattern. The liquid material is a solution containing, for example, an insulating resin material (e.g., a polyimide precursor and/or a polyimide (soluble)). The polyimide precursor and/or polyimide solution may contain metal nanoparticles or metal oxide nanoparticles. The viscosity or the like of the liquid material is adjusted so that a pattern having a predetermined line width can be formed using an inkjet technique. Alternatively, the liquid material may be a conductive nano-ink containing ITO nanoparticles or Ti nanoparticles. The viscosity or the like of the conductive nano-ink is also adjusted so that a pattern having a predetermined line width can be formed using an inkjet technique. The inkjet technique can be performed using, for example, an ultra-fine inkjet processing device manufactured by SIJ Technology, Inc. The ultra-fine inkjet processing device can be used to form a pattern having a line width of 3 μm.

The polyimide precursor (polyamic acid) and/or polyimide (soluble) solution is heated to form a polyimide layer. In addition, the nano-ink containing ITO nanoparticles or Ti nanoparticles is heated to form a nanoparticle sintered material layer. These heating steps are performed using, for example, infrared (IR) laser. By using the IR laser, only the pattern formed of the liquid material can be selectively and efficiently heated, and therefore, the other constituent elements can be inhibited from being degraded due to heat. Note that in order to inhibit the degradation due to heat, the heating temperature preferably does not exceed 400° C. The duration of the irradiation with the IR laser may be appropriately set, depending on the irradiation intensity of the IR laser, the absorption efficiency of the liquid material, reaction rates (e.g., an imidation reaction rate and a nanoparticle sintering reaction rate), etc. The IP laser is, for example, CO₂ laser, YAG laser, or semiconductor laser. The wavelength of the laser light may be appropriately selected, depending on the absorption wavelength of the liquid material. IR laser for laser sintering (selective laser sintering (SLS)) in a 3D printer or the like can be preferably used.

Note that if the liquid material contains a large amount of a solvent or is highly volatile, bubbles may be generated due to rapid heating, so that a dense film may not be obtained. To prevent this, the solvent (at least, a portion thereof) contained in the liquid material is preferably removed prior to the heating step. The solvent is removed by heating at a temperature lower than or equal to the boiling point of the solvent, for example, a temperature of 100° C. or lower. Pressure may be reduced, or heating may be conducted under reduced pressure. This heating is conducted using, for example, an electric furnace.

Next, a predetermined pattern is drawn on the lower layer 16A, and on the interconnect 14 on both sides of the broken portion 14b, using a conductive nano-ink containing metal nanoparticles. This step can also be performed using, for example, an inkjet technique. At this time, if an ultra-fine inkjet processing device having a plurality of heads (e.g., a wide-range inkjet processing device manufactured by SIJ Technology, Inc.) is used, the application of the liquid material for the lower layer 16A and the application of the conductive nano-ink can be conducted using a single inkjet processing device.

Next, the conductive nano-ink in the predetermined pattern is sintered by heating to obtain a metal nanoparticle sintered material-containing layer 18A. The conductive nano-ink can also be sintered using, for example, the above IR laser. The same IR laser that is used to form the lower layer 16A may be used, or alternatively, another IR laser may be prepared, depending on wavelength or intensity. The sintering using IR laser is preferably conducted at a temperature of, for example, 100-400° C. Thus, a metal nanoparticle sintered material-containing layer having a resistivity of 1×10−5 Ω·cm or less can be obtained. If the temperature is lower than 100° C., a dense film may not be obtained, and if the temperature is higher than 400° C., peripheral constituent elements may be degraded due to heat.

The solvent (at least a portion thereof) contained in the conductive nano-ink is preferably removed prior to the sintering of the conductive nano-ink. If the liquid material contains a large amount of a solvent or is highly volatile, bubbles may be generated due to rapid heating, or the nanoparticles may be scattered, so that a good-quality film may not be obtained. The solvent is removed by heating at a temperature lower than or equal to the boiling point of solvent, for example, a temperature of 100° C. or lower. Pressure may be reduced, or heating may be conducted under reduced pressure. This heating is conducted using, for example, an electric furnace. The same equipment that is used to form the lower layer 16A may be used for the removal of the solvent.

In order to repair the broken portion 14b of the interconnect 14, the multilayer structure of the lower layer 16A and the metal nanoparticle sintered material-containing layer 18A is herein used. The embodiment of the present invention is not limited to this. The embodiment of the present invention can be widely used in formation of a conductive linear pattern on a surface of an inorganic insulating material. The linear pattern may be non only in a straight-line shape but also in a curved-line shape or a bent pattern. In addition, the linear pattern is not limited to an interconnect, or alternatively, may be an RF antenna pattern, for example. This is also true of embodiments described be low.

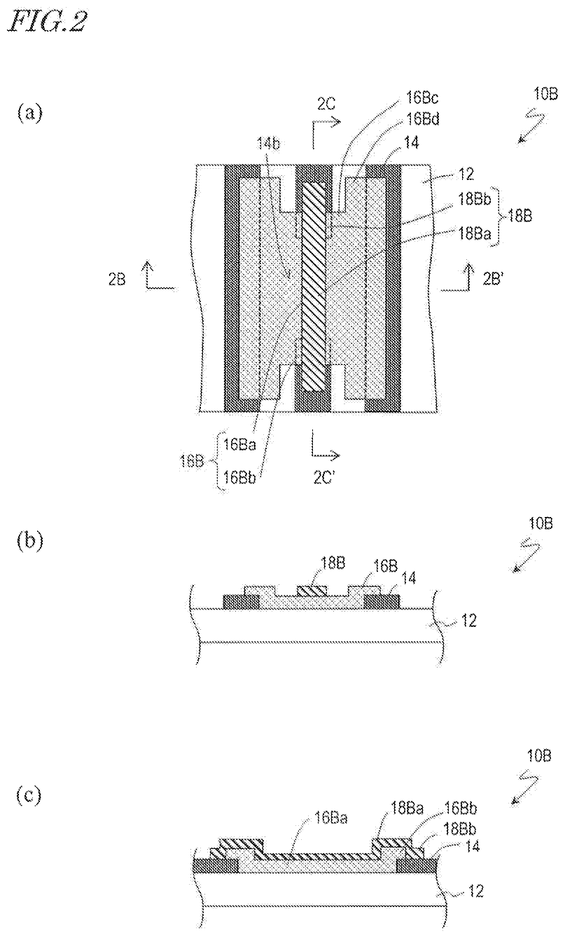

A structure of a break-repaired portion in a TFT substrate 10B according to another embodiment of the present invention will be described with reference to FIG. 2. Prior to repairing of a broken line, the TFT substrate 10B has the same structure as that of the TFT substrate 10A, and therefore, like constituent elements are designated by like reference signs and may not be described herein.

FIG. 2(a) is a plan view schematically showing a break-repaired portion in the TFT substrate 10B. FIG. 2(b) is a schematic cross-sectional view taken along line 2B-2B′ in FIG. 2(a). FIG. 2(c) is a schematic cross-sectional view taken along line 2C-2C′ in FIG. 2(a).

The TFT substrate 10B has a lower layer 16B having insulating properties that is formed, extending on interconnects adjacent to an interconnect 14 having a broken portion 14b. Specifically, as shown in FIG. 2(a), the lower layer 16B has an H-shape as viewed in a direction normal to a substrate 12, and has a portion 16Bc that is shorter than a metal nanoparticle sintered material-containing layer 18B and a portion 16Bd that is longer than the metal nanoparticle sintered material-containing layer 18B. The portion l6Bd that is longer than the metal nanoparticle sintered material-containing layer 18B is formed, covering a portion of an interconnect 14 adjacent to the interconnect 14 having the broken portion 14b. In the example shown, the lower layer 16B has two of the portions 16Bd that are longer than the metal nanoparticle sintered material-containing layer 18B, and are formed, covering a portion of each of the two interconnects 14 adjacent to the interconnect 14 having the broken portion 14b. The shorter portion 16Bc and the two longer portions 16Bd on both sides of the shorter portion 16Bc are continuously formed so that the lower layer 16B covers spaces between the interconnect 14 having the broken portion 14b and the interconnects 14 adjacent thereto (see. FIGS. 2(a) and 2(b)).

In addition, like the lower layer 16A of FIG. 1, the lower layer 16B is formed, extending on the interconnect 14 on both sides of the broken portion 14b shown in FIG. 1. Specifically, the lower layer 16B has a portion 16Ba that is formed on a surface of the substrate 12 that is exposed by the broken portion 14b of the interconnect 14, and portions 16Bb formed on the interconnect 14 on both sides of the broken portion 14b (see FIG. 2(c)).

The metal nanoparticle sintered material-containing layer 18B has a portion 18Ba formed on the lower layer 16B. The metal nanoparticle sintered material-containing layer 18B has portions 18Bb formed on the interconnect 14 on both sides of the broken portion 14b. The cross-sectional structure of FIG. 2(c) is substantially the same as that of FIG. 1(c).

The lower layer 16B has insulating properties and may have a greater width, unlike the lower layer 16A having conductivity (see FIG. 1). Therefore, the patterning precision of the lower layer 16B may be lower than that of the lower layer 16A. Therefore, the manufacturing cost can be reduced. For example, in order to form the lower layer 16B, an ultra-fine inkjet head for forming the lower layer 16A is not required, and a lower-cost inkjet head can be used. A method for repairing a broken line in a TFT substrate according to an embodiment of the present invention performs, for example, a step of identifying a plurality of broken portions on a mother substrate, a step of applying a material for a lower layer to each of the plurality of broken portions using an inkjet technique, and a step of heating the material of each lower layer using IR laser, successively, to form the lower layers at all of the plurality of broken portions. Thereafter, for the plurality of broken portions, a step of drawing a conductive nano-ink containing metal nanoparticles on the lower layer and on both sides of the broken portion using an inkjet technique, and a step of sintering the conductive nano-ink by heating using IR laser, are successively performed. A plurality of broken portions on a mother substrate can be successively repaired using a single inkjet device and a single IR laser. Therefore, broken-line repairing can be performed with high mass-production efficiency and reliability. According to the embodiment of the present invention, a conductive pattern in a metal nanoparticle sintered material-containing layer is formed on a lower layer can be similarly formed with high mass-productivity.

### INDUSTRIAL APPLICABILITY

The present invention is used in conductive patterns such as various wiring boards and RF antennas, methods for forming a conductive pattern, and broken-line repairing methods. Particularly, the present invention is suitably used in repairing of a broken line in a wiring board (typically, a TFT substrate) used in a large-sized, high-definition display panel.

### REFERENCE SIGNS LIST

10A, 10B: TFT substrate
12: substrate
14: interconnect
14b: broken portion
16A, 16B: lower layer
18A, 18B: metal nanoparticle sintered material-containing layer

1. A conductive pattern formed on a surface of an inorganic insulating material, wherein
the conductive pattern has a lower layer in direct contact with the surface of the inorganic insulating material, and a metal nanoparticle sintered material-containing layer formed on the lower layer, and wherein
the conductive pattern includes a linear pattern formed on the surface of the inorganic insulating material, and
the linear pattern has
a linear conductive layer having a broken portion,
the lower layer formed in direct contact with the surface of the inorganic insulating material exposed at at least the broken portion, and
the metal nanoparticle sintered material-containing layer continuously formed on the lower layer, and on the linear conductive layer on both sides of the broken portion.

2. (canceled)

3. The conductive pattern of claim 1, wherein
the linear conductive layer is formed of a metal layer.

4. The conductive pattern of claim 1, wherein
the metal nanoparticle sintered material-containing layer has a resistivity of 1×10⁻⁵ Ω·cm or less.

5. The conductive pattern of claim 1, wherein
the lower layer has insulating properties.

6. The conductive pattern of claim 1, wherein
the lower layer contains a polyimide.

7. The conductive pattern of claim 5, wherein
the lower layer further contains metal nanoparticles or metal oxide nanoparticles.

8. The conductive pattern of claim 1, wherein
the lower layer has conductivity, and has a resistivity higher than that of the metal nanoparticle sintered material-containing layer.

9. The conductive pattern of claim 8, wherein
the lower layer contains an ITO nanoparticle sintered material or a Ti nanoparticle sintered material.

10. A method for forming the conductive pattern of claim 1, wherein
a step of forming the metal nanoparticle sintered material-containing layer includes a step of applying a conductive nano-ink containing metal nanoparticles using an inkjet technique.

11. A broken-line repairing method comprising:
step A of preparing a substrate having a plurality of interconnects on a surface of an inorganic insulating material;
step B of identifying a broken portion in the plurality of interconnects;
step C of forming a lower layer in direct contact with the surface of the inorganic insulating material exposed at the broken portion;
step D of drawing a predetermined pattern on the lower layer, and on an interconnect having the broken portion of the plurality of interconnects on both sides of the broken portion, using a conductive nano-ink containing metal nanoparticles; and
step E of sintering the conductive nano-ink of the predetermined pattern by heating.

12. The broken-line repairing method of claim 11, wherein
step C is a step of forming the lower layer such that the lower layer extends on the interconnect having the broken portion of the plurality of interconnects on both sides of the broken portion.

13. The broken-line repairing method of claim 11, wherein
step C is a step of forming the lower layer using an insulating material such that the lower layer extends on an interconnect adjacent to the interconnect having the broken portion.

14. The broken-line repairing method of claim 11, wherein
step D is performed using an inkjet technique.

15. The broken-line repairing method of claim 11, wherein
step E is performed using infrared laser.
